(19) United States
(12) Patent Application Publication
(10) Pub. No.: US 2007/0284616 A1
(43) Pub. Date: Dec. 13, 2007

(54) Light emitting transistor

(75) Inventors: Won Ha Moon, Suwon (KR); Chang Hwan Choi, Seongnam (KR); Young Nam Hwang, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/808,158

(22) Filed: Jun. 7, 2007

(30) Foreign Application Priority Data
Jun. 8, 2006 (KR) 10-2006-0051214

(51) Int. Cl. H01L 31/00

(52) U.S. Cl. 257/197

(57) ABSTRACT

A light emitting transistor comprises a first conductivity-type collector layer formed on a substrate; a second conductivity-type base layer formed on a predetermine region of the collector layer; a collector electrode formed on the collector layer where the base layer is not formed; a first conductivity-type emitter layer formed on a predetermine region of the base layer; a base electrode formed on the base layer where the emitter layer is not formed; an emitter electrode formed on the emitter layer; a first activation layer formed between the collector layer and the base layer; and a second activation layer formed between the base layer and the emitter layer.

### CROSS-REFERENCE TO RELATED APPLICATIONS

This application claims the benefit of Korean Patent Application No. 10-2006-0051214 filed with the Korean Intellectual Property Office on Jun. 8, 2006, the disclosure of which is incorporated herein by reference.

### BACKGROUND OF THE INVENTION

1. Field of the Invention

The present invention relates to a light emitting transistor which can obtain optical and electrical characteristics at the same time.

2. Description of the Related Art

In general, a light emitting diode (LED) generates minority carriers (electrons or holes) injected by using the p-n junction structure of a semiconductor, and recombines the minority carriers so as to emit light. In other words, if a forward voltage is applied to a specific element of semiconductor, electrons and holes are recombined while moving through a joined portion between an anode and a cathode. Since energy in such a state is smaller than energy in a state where the electrons and holes are separated, light is emitted due to a difference in energy occurring at this time.

Such an LED can irradiate light with high efficiency by using a low voltage. Therefore, the LED is used in a home appliance, a remote control, an electronic display board, a marker, an automation equipment, or the like.

Meanwhile, most of semiconductor electronic elements are implemented with transistors, and transistors formed of group III-V and II-VI nitride semiconductors are manufactured so as to be used in various fields.

However, researches in transistors for light emission have almost never carried out. In this technical field, a new method for obtaining optical and electrical characteristics is being required.

### SUMMARY OF THE INVENTION

An advantage of the present invention is that it provides a light emitting transistor which can obtain optical and electrical characteristics at the same time.

Additional aspect and advantages of the present general inventive concept will be set forth in part in the description which follows and, in part, will be obvious from the description, or may be learned by practice of the general inventive concept.

According to an aspect of the invention, a light emitting transistor comprises a first conductivity-type collector layer formed on a substrate; a second conductivity-type base layer formed on a predetermine region of the collector layer; a collector electrode formed on the collector layer where the base layer is not formed; a first conductivity-type emitter layer formed on a predetermine region of the base layer; a base electrode formed on the base layer where the emitter layer is not formed; an emitter electrode formed on the emitter layer; a first activation layer formed between the collector layer and the base layer; and a second activation layer formed between the base layer and the emitter layer.

According to another aspect of the invention, a light emitting transistor comprises a first conductivity-type collector layer formed on a substrate; a second conductivity-type base layer formed on a predetermine region of the collector layer; a collector electrode formed on the collector layer where the base layer is not formed; a first conductivity-type emitter layer formed on a predetermine region of the base layer; a base electrode formed on the base layer where the emitter layer is not formed; an emitter electrode formed on the emitter layer; and an activation layer formed between the collector layer and the base layer.

According to a further aspect of the invention, a light emitting transistor comprises a first conductivity-type collector layer formed on a substrate; a second conductivity-type base layer formed on a predetermine region of the collector layer; a collector electrode formed on the collector layer where the base layer is not formed; a first conductivity-type emitter layer formed on a predetermine region of the base layer; a base electrode formed on the base layer where the emitter layer is not formed; an emitter electrode formed on the emitter layer; and an activation layer formed between the base layer and the emitter layer.

According to a still further aspect of the invention, the first conductivity type is n-type, and the second conductivity type is p-type.

According to a still further aspect of the invention, the first conductivity type is p-type, and the second conductivity type is n-type.

According to a still further aspect of the invention, the collector layer, the base layer, the emitter layer, and the activation layers are formed of group II-VI or III-V compound semiconductors.

According to a still further aspect of the invention, the II-VI compound semiconductors are ZnSe, ZnTe, ZnSeTe, ZnS, ZnO, CdSe, CdS, CdTe, ZnCdS, ZnCdSe, ZnCdSeTe, ZnCdSTe and the like.

According to a still further aspect of the invention, the III-V compound semiconductors are GaAs, GaAlAs, GaInAs, InAs, InP, InSb, GaSb, GaInSb, GaN, GaInN and the like.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a plan view illustrating the structure of a light emitting transistor according to an embodiment of the invention;

FIGS. 2 to 4 are sectional views taken along I-I′ line of FIG. 1; and

FIGS. 5A and 5B are diagrams showing an equivalent circuit and an I-V curve of the light emitting transistor according to the embodiment of the invention, respectively.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures. In the drawings, the thicknesses of layers and regions are exaggerated for clarity.

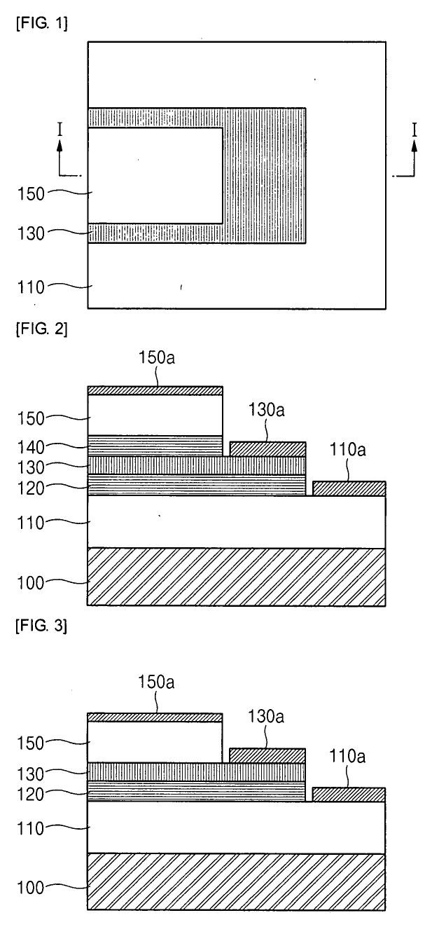

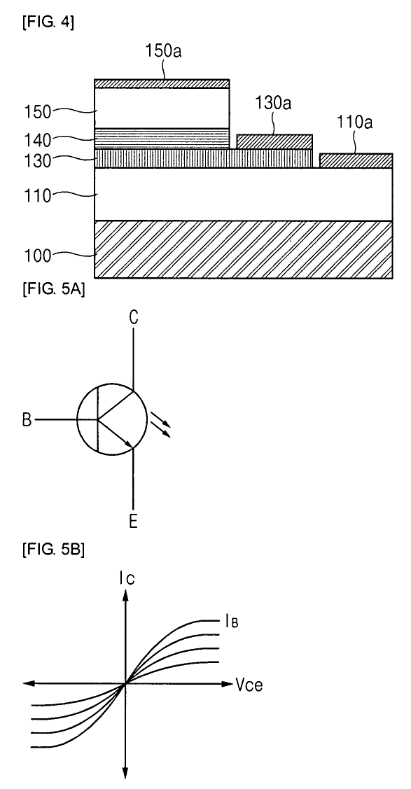

Hereinafter, a light emitting transistor according to an embodiment of the present invention will be described in detail with reference to FIGS. 1 to 5.

FIG. 1 is a plan view illustrating the structure of a light emitting transistor according to an embodiment of the invention, and FIGS. 2 to 4 are sectional views taken along I-I′ line of FIG. 1.

As shown in FIGS. 1 and 2, the light emitting transistor according to the invention basically has a bipolar junction structure.

That is, the light emitting transistor includes a substrate 100, a first conductivity-type collector layer 110 formed on the substrate 100, a second conductivity-type base layer 130 formed on a predetermined region of the collector layer 110, and a first conductivity-type emitter layer 150 formed on a predetermined region of the base layer 130, the emitter layer 150 having the same conductivity type as the collector layer 110.

The first conductivity type is n-type, and the second conductivity type is p-type. The collector layer 110 and the emitter layer 150 may be formed of n-type semiconductors, and the base layer 130 may be formed of a p-type semiconductor. The collector layer 110 and the emitter layer 150 formed of n-type semiconductors may be doped with Si or the like, and the base layer 130 formed of a p-type semiconductor may be doped with Mg or the like.

On the contrary, the first conductivity type may be p-type, and the second conductivity type may be n-type. Further, the collector layer 110 and the emitter layer 150 may be formed of p-type semiconductors, and the base layer 130 may be formed of an n-type semiconductor.

The emitter layer 150 is a region to which holes or electrons are injected, the collector layer 110 is a region in which injected holes or electrons are focused, and the base layer 130 is an intermediate region between the emitter layer 150 and the collector layer 110.

On the collector layer 110 where the base layer 130 is not formed, a collector electrode 110a is formed.

On the base layer 130 where the emitter layer 150 is not formed, a base electrode 130a is formed.

On the emitter layer 150, an emitter electrode 150a is formed.

The collector electrode 110a, the base electrode 130a, and the emitter electrode 150a come in ohmic contact with the collector layer 110, the base layer 130, and the emitter layer 150, respectively. Preferably, the respective electrodes 110a, 130a, and 150a are formed of at least one metal selected from the group consisting of Pd, Ti, Al, Pt, Au, Ni and Cr or an alloy thereof.

The light emitting transistor according to the invention further includes a first activation layer 120 formed between the collector layer 110 and the base layer 130 and a second activation layer 140 formed between the base layer 130 and the emitter layer 150.

Instead of the above-described structure including both of the first and second activation layers 120 and 140, the light emitting transistor according to the invention may further include only the activation layer 120 formed between the collector layer 110 and the base layer 130, as shown in FIG. 3. Alternately, the light emitting transistor may further include only the activation layer 140 formed between the base layer 130 and the emitter layer 150.

The activation layers 120 and 140, the collector layer 110, the base layer 130, and the emitter layer 150 may be formed of group II-VI or III-V compound semiconductors.

As for the group II-VI compound semiconductors, ZnSe, ZnTe, ZnSeTe, ZnS, ZnO, CdSe, CdS, CdTe, ZnCdS, ZnCdSe, ZnCdSeTe, ZnCdSTe and the like can be used. As for the group III-V compound semiconductors, GaAs, GaAlAs, GaInAs, InAs, InP, InSb, GaSb, GaInSb, GaN, GaInN and the like can be used.

FIGS. 5A and 5B are diagrams showing an equivalent circuit and an I-V curve of the light emitting transistor according to the embodiment of the invention.

As shown in FIGS. 5A and 5B, the light emitting diode including three terminals of collector C, base B, and emitter E can adjust the intensity of light generated from the activation layer through the adjustment of the base B, and the magnitude of collector current is adjusted by a base voltage.

That is, carriers flowing in the emitter E and the collector C are electrons and holes. When a voltage is applied to the base B, the barrier of the base B is reduced in height such that carriers easily move from the emitter E to the collector C. Then, a current flowing in the collector C is amplified.

As described above, the light emitting transistor according to the invention has a bipolar junction structure including the collector layer 110, the base layer 130, and the emitter layer 150. Between the collector layer 110 and the base layer 130 and between the base layer 130 and the emitter layer 150, the activation layers 120 and 140 emitting light are respectively formed. Therefore, an optical and electrical output can be amplified or can be switched from on-state to off-state or from off-state to on-state, in accordance with a bias direction of each terminal.

According to the light emitting transistor of the invention, the activation layers emitting light are respectively formed between the collector layer and the base layer and between the base layer and the emitter layer in the bipolar junction structure including the collector layer, the base layer, and the emitter layer. Therefore, it is possible to obtain optical and electrical characteristics at the same time.

Further, the intensity of light can be adjusted by the adjustment of the base terminal. In accordance with a bias direction of each terminal, an optical and electrical output can be amplified or can be switched from on-state to off-state or from off-state to on-state.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A light emitting transistor comprising:
a first conductivity-type collector layer formed on a substrate;
a second conductivity-type base layer formed on a predetermine region of the collector layer;
a collector electrode formed on the collector layer where the base layer is not formed;
a first conductivity-type emitter layer formed on a predetermine region of the base layer;
a base electrode formed on the base layer where the emitter layer is not formed;
an emitter electrode formed on the emitter layer;
a first activation layer formed between the collector layer and the base layer; and
a second activation layer formed between the base layer and the emitter layer.

2. A light emitting transistor comprising:
a first conductivity-type collector layer formed on a substrate;
a second conductivity-type base layer formed on a predetermine region of the collector layer;
a collector electrode formed on the collector layer where the base layer is not formed;
a first conductivity-type emitter layer formed on a predetermine region of the base layer;
a base electrode formed on the base layer where the emitter layer is not formed;
an emitter electrode formed on the emitter layer; and
an activation layer formed between the collector layer and the base layer.

3. A light emitting transistor comprising:
a first conductivity-type collector layer formed on a substrate;
a second conductivity-type base layer formed on a predetermine region of the collector layer;
a collector electrode formed on the collector layer where the base layer is not formed;
a first conductivity-type emitter layer formed on a predetermine region of the base layer;
a base electrode formed on the base layer where the emitter layer is not formed;
an emitter electrode formed on the emitter layer; and
an activation layer formed between the base layer and the emitter layer.

4. The light emitting transistor according to claim 1,
wherein the first conductivity type is n-type, and the second conductivity type is p-type.

5. The light emitting transistor according to claim 1,
wherein the first conductivity type is p-type, and the second conductivity type is n-type.

6. The light emitting transistor according to claim 1,
wherein the collector layer, the base layer, the emitter layer, and the activation layers are formed of group II-VI or III-V compound semiconductors.

7. The light emitting transistor according to claim 6,
wherein the II-VI compound semiconductors are ZnSe, ZnTe, ZnSeTe, ZnS, ZnO, CdSe, CdS, CdTe, ZnCdS, ZnCdSe, ZnCdSeTe, ZnCdSTe and the like.

8. The light emitting transistor according to claim 6,
wherein the III-V compound semiconductors are GaAs, GaAlAs, GaInAs, InAs, InP, InSb, GaSb, GaInSb, GaN, GaInN and the like.
